(19) United States
(12) Patent Application Publication
(10) Pub. No.: US 2002/0009842 A1
(43) Pub. Date: Jan. 24, 2002

(54) High-voltage device and method for manufacturing high-voltage device

(76) Inventor: Ming-Tsung Tung, Chutung Town (TW)

Correspondence Address: J.C. PATENTS INC., Suite 250, 4 Venture, Irvine, CA, 92618, US

(21) Appl. No.: 09/940,351

(22) Filed: Aug. 27, 2001

Related U.S. Application Data
(62) Division of application No. 09/476,826, filed on Jan. 3, 2000.

(51) Int. Cl. H01L 21/00; H01L 21/84; H01L 21/8238; H01L 21/336

(52) U.S. Cl. 438/199; 438/153; 438/154

(57) ABSTRACT

A high-voltage device is proposed. A first well region with the first conductive type is located in a substrate. Several isolation regions are located on the first well region. Each isolation region comprises two field oxide layers on either side of a shallow trench isolation structure. A gate structure is formed on the first well region between the isolation regions and the gate structure expands on a portion of the isolation regions. A source/drain region with the second conductive type is located in the first well region exposed by the gate structure and the isolation regions. A second well region with a second conductive type is located in the first well region beneath the isolation region and the source/drain region. A first doped region with the second conductive type is located in the second well region beneath each of the field oxide layers. A second doped region with the first conductive type is located in the second well region beneath each of the shallow trench isolation structures.

### BACKGROUND OF THE INVENTION

Field of Invention

The present invention relates to a semiconductor and a method for manufacturing a semiconductor. More particularly, the present invention relates to a high-voltage device and a method for manufacturing a high-voltage device.

Description of Related Art

A high voltage device is one of the most important devices utilized in a highly integrated circuit. Erasable programmable read only memory (EPROM) and flash memory are two of the high-voltage devices most often used in computers and electronic products.

Due to the increasing number of semiconductor devices incorporated in integrated circuits, the size of transistors needs to be decreased. Accordingly, as the channel length of the transistors is decreased, the operating speed is increased. However, the short channel effect caused by the reduced channel length is becoming serious. If the voltage level is fixed as the channel length is shortened, the strength of the electrical field is increased according to the equation, electrical field=electrical voltage/channel length. Thus, as the strength of the electrical field increases, the electron energy increases and electrical breakdown is likely to occur.

In the conventional high-voltage device. the formation of an isolation layer is used for the purpose of increasing the channel length. Hence, the high-voltage device is able to work normally at a high electrical voltage.

FIG. 1 is a schematic. cross-sectional view showing a portion of a conventional high-voltage device.

As shown in FIG. 1. two field oxide layers 102 are formed in the P-type silicon substrate 100. A gate oxide layer 112 is formed on the substrate 100 between the two field oxide layers 102. The field oxide layers 102 are used to increase the channel length between an N⁺-type source region 106 and an N⁻-type drain region 108. An N⁻-type doped region 116 expands from a portion of the substrate beneath the source region 106 to the far side of one of the field oxide layers 102. An N⁻-type doped region 118 expands from a portion of the substrate beneath the drain region 108 to the far side of the other of the field oxide layers 102. A portion of a gate 104 is located on the gate oxide layer 112 and the other portion of the gate 104 is positioned on the field oxide layers 102. The N⁻-type doped regions 116 and 118 are used as drift regions for carriers while the device is operated.

In order to increase the breakdown voltage of the high-voltage device. it is necessary to decrease the dopant concentration of the drift region, which concentration is the dopant concentration of the N⁻-type doped regions 116 and 118. However, the current-driving performance and the channel conductivity between the source region 106 and the drain region 108 under the gate electrode 104 in the substrate 100 are decreased.

Additionally, when the manufacturing technique is promoted to a sub-quarter micron level, for example. a line width of 0.18 microns or less. it is difficult to decrease the typical design rule of the high-voltage device.

### SUMMARY OF THE INVENTION

The invention provides a high-voltage device constructed on a substrate. The high-voltage device comprise a first well region with the first conductive type. a second well region with a second conductive type, several isolation regions a first doped region with the second conductive type, a second doped region with the first conductive type, a gate structure and a source/drain region with the second conductive type. The first well region is located in the substrate. The isolation regions are located on the first well region. Each of the isolation regions comprises two field oxide layers on either side of a shallow trench isolation structure. The gate structure is formed on the first well region between the isolation regions and the gate structure expands on a portion of the isolation regions. The source/drain region is located in the first well region exposed by the gate structure and the isolation regions. The second well region is located in the first well region beneath the isolation region and the source/drain region. The first doped region is located in the second well region beneath each of the field oxide layers. The second doped region is located in the second well region beneath each of the shallow trench isolation structures.

The invention also provides a method for manufacturing a high-voltage CMOS device. A substrate having a first P-type well region and a first N-type region formed therein is provided. Several first isolation regions and second isolation regions are respectively formed on the first P-type well and the first N-type well. Every first isolation region comprises two first field oxide layers on either side of a first shallow trench isolation structure and every second isolation region comprises two second field oxide layers on either side of a second shallow trench isolation structure. Furthermore, a first N-type doped region and a first P-type doped region are respectively formed beneath each of the first oxide layers and each of the second field oxide layers. A second P-type doped region and a second P-type well region are respectively formed beneath each of the first shallow trench isolation structures and in the first N-type well region under the second isolation regions. A second N-type doped region and a second N-type well region are respectively formed beneath each of the second shallow trench isolation structures and in the first P-type well region under the first isolation regions. A first and a second gate structure are respectively formed on the first P-type well region between the first isolation regions and on the first N-type well region between the second isolation regions. An N-type source/drain region is formed in the second N-type well region exposed by the first gate structure and the first isolation regions. A P-type source/drain region is formed in the second P-type well region exposed by the second gate structure and the second isolation regions.

In the method described above, when the first conductive type is N-type, the second conductive type is P-type. Conversely when the first conductive type is P-type, the second conductive type is N-type.

In the invention, the depletion regions exist between the second P-type doped region and the second N-type well region and between the second N-type doped region and the second P-type well region. Furthermore, each depth of the second N-type well region and the second P-type well region is larger than that of the conventional N⁻-type doped regions 116 and 118, so that the intensity of the electric field caused by the high voltage applied on the N-type source/drain region and on the P-type source/drain region is decreased. Therefore, the crowding electric force lines effect does not occur. Hence, it can provide a bulk breakdown near the N-type source/drain region and near the P-type source/drain region.

It is to be understood that both the foregoing general description and the following detailed description are exemplary. and are intended to provide further explanation of the invention as claimed.

### BRIEF DESCRIPTION OF THE DRAWINGS

The accompanying drawings are included to provide a further understanding of the invention. and are incorporated in and constitute a part of this specification. The drawings illustrate embodiments of the invention and. together with the description. serve to explain the principles of the invention. In the drawings,

FIG. 1 is a schematic, cross-sectional view showing a portion of a conventional high-voltage device; and

FIGS. 2A through 2D are schematic. cross-sectional views of the process for manufacturing a high-voltage CMOS device in a preferred embodiment according to the invention.

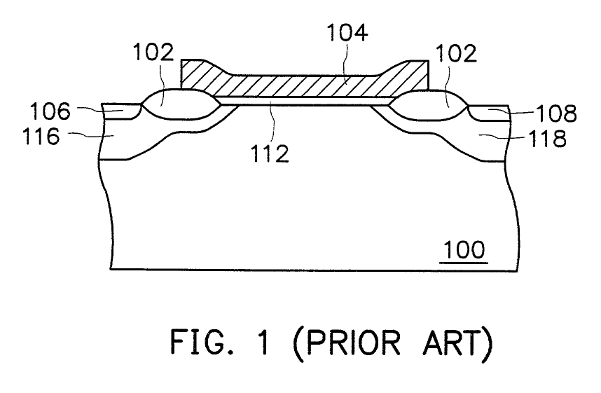

### DESCRIPTION OF THE PREFERRED EMBODIMENTS

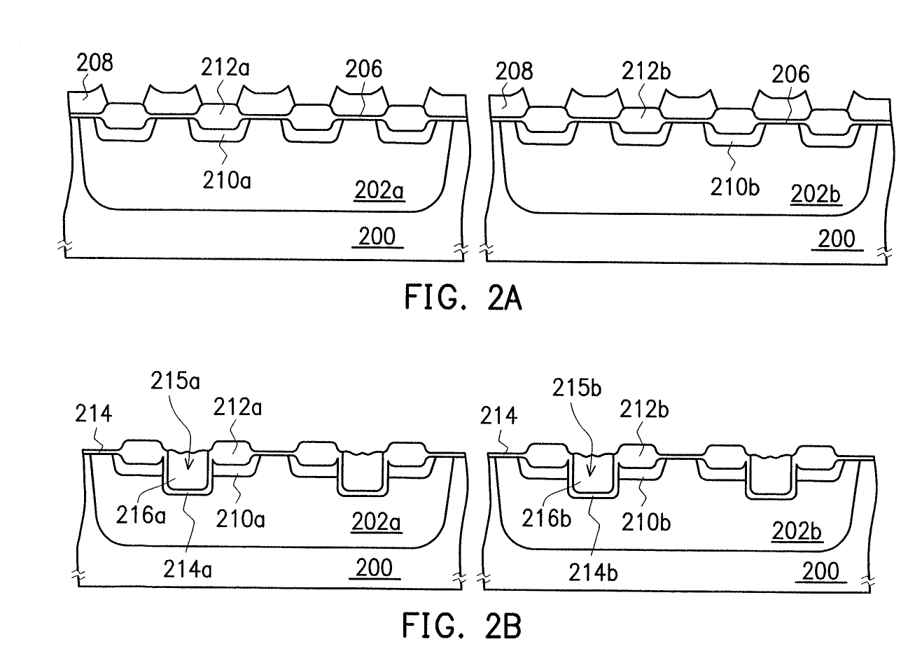

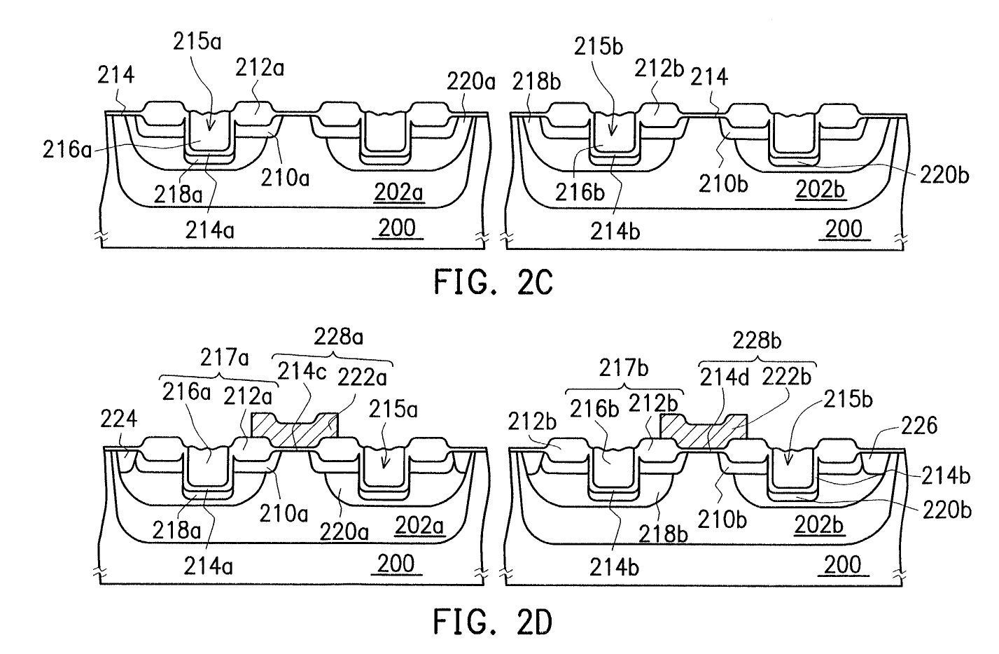

FIGS. 2A through 2D are schematic. cross-sectional views of the process for manufacturing a high-voltage complementary metal-oxide semiconductor (CMOS) device in a preferred embodiment according to the invention.

As shown in FIG. 2A, a substrate 200 is provided. The substrate 200 possesses a well region 202a with a first conductive type and a well region 202b with a second conductive type. The dosages of the well regions 202a and 202b are each about 1×10¹²˜1×10¹³ atoms/cm².

Thereafter, a drive-in process is performed. A pad oxide layer 206 and a patterned silicon nitride layer 208 are formed over the substrate 200 in sequence. The patterned silicon nitride layer 208 exposes portions of the pad oxide layer 206 above the well regions 202a and 202b. The exposed portions of the pad oxide layer 206 are used to form field oxide layers in the subsequent process.

A doped region 210a with the second conductive type and a doped region 210b with the first conductive type are respectively formed in the well regions 202a and 202b under the exposed portions of the pad oxide layer 206. The dosages of the doped regions 210a and 210b are each about 1×10¹²˜1×10¹⁴ atoms/cm². Field oxide layers 212a and 212b are respectively formed on the doped regions 210a and 210b.

As shown in FIG. 2B, the patterned silicon nitride layer 208 and the pad oxide layer 206 are removed in sequence. A trench 215a is formed in every other space between the field oxide layers 210a in the substrate 200 while trenches are respectively formed in every other space between the field oxide layers 210b in the substrate 200. An oxide layer 214 is formed over the substrate 200. Portions of the oxide layer 214 respectively located in the trenches 215a and 215b are respectively denoted as linear layers 214a and 214b. The method for forming the oxide layer 214 can be thermal oxidation and the thickness of the oxide layer 214 is about 100-500 angstroms.

Oxide layers 216a and 216b are formed in the trenches 215a and 215b and fill the trenches 215a and 215b. The oxide layers 216a and 216b are used as shallow trench isolation structures. The method for forming the shallow trench isolation structures 216a and 216b comprises the steps of forming an oxide layer (not shown) on the oxide layer 214 with a thickness of about 5000-9000 angstroms by atmospheric pressure chemical vapor deposition (APCVD). and then performing a densification process to reinforce the compactness of the oxide layer in the trenches 215a and 215b. The densification process is performed in a temperature of about 1000 degrees centigrade for 10-30 minutes. A chemical-mechanical polishing (CMP) is performed to remove a portion of the oxide layer, thereby to expose the surface of the oxide layer 214 and to form the oxide layers 216a and 216b. The structure constructed by the field oxide layer 212a, the shallow trench isolation structure 216a and the field oxide layer 212a is denoted as an isolation region 217a (FIG. 2D). Simultaneously. the structure constructed by the field oxide layer 212b, the shallow trench isolation structure 216b and the field oxide layer 212b is denoted as an isolation region 217b (FIG. 2D).

As shown in FIG. 2C, a doped region 218a with the first conductive type is formed in the well region 202a beneath the shallow trench isolation structure 216a while a well region 218b with the first conductive type is formed in the well region 202b under the isolation region 217b (FIG. 2D). Each dosage of the doped region 218a and well region 218b is about 1×10¹³ atoms/cm² Additionally the well region 218b expands from the interface between the well region 202b and the isolation region 217b into the well region 202b and laterally expands far away from a portion of the well region 202b between the isolation regions 217b.

A well region 220a with the second conductive type is formed in the well region 202a beneath the isolation region 217a while a doped region 220b with the second conductive type is formed in the well region 218b under the shallow trench isolation structure 216b. The dosages of the well region 220a and doped region 220b are each about 1×10¹³ atoms/cm². Additionally, the well region 220a expands from the interface between the well region 202a and the isolation region 217a into the well region 202a and laterally expands far away from a portion of the well region 202a between the isolation regions 217a.

As shown in FIG. 2D, an oxide layer (not shown) and a conductive layer (not shown) are formed over the substrate 200 in sequence. The conductive layer. the oxide layer and the oxide layer 214 layer are patterned to form a gate electrode 222a and a gate oxide layer 214c on the well region 202a between the isolation regions 217a and to form a gate electrode 222b and a gate oxide layer 214d on the well region 202b between the isolation regions 217b. The patterned conductive layer is transformed into the gate electrodes 222a and 222b and the patterned oxide layer and the patterned oxide layer 214 together form the gate oxide layers 214c and 214d. The gate structure 228a constructed by the gate electrode 222a and the gate oxide layer 214c is located on the well region 202a and laterally expands over a portion of the isolation regions 217a. The gate structure 228b constructed by the gate electrode 222b and the gate oxide layer 214d is located on the well region 202b and laterally expands over a portion of the isolation regions 217b.

A source/drain region 224 with the second conductive type is formed in the well region 220a exposed by the gate structure 228a and the isolation regions 217a. The dosage of the source/drain region 224 is about 1×10¹⁵ atoms/cm².

A source/drain region 926 with the first conductive type is formed in the well regions 218b exposed by the gate structure 228b and the isolation regions 217b. Therefore, the manufacturing process for forming the high-voltage CMOS device is finished. The dosage of the source/drain region 226 is about 1×10¹⁵ atoms/cm².

Notably, when the first conductive type is N-type, the second conductive type is P-type. Simultaneously when the first conductive type is P-type, the second conductive type is N-type. The method according to the invention can be applied not only to the formation of a CMOS. but also to the formation of a single-type MOS, such as NMOS or PMOS.

In the invention. the well region 202a with the first conductive type is located in the substrate 200. Several isolation regions 217a are located on the well region 202a. Each of the isolation regions 217a is constructed by two field oxide layers 212a on either side of one shallow trench isolation structure 216a. The gate structure 228a is positioned on the well region 202a between the isolation regions 217a and expands onto the isolation regions 217a. The source/drain region 224 with the second conductive type is located in the well region 202a exposed by the gate structure 228a and the isolation regions 217a. The doped region 210a with the second conductive type is located beneath each of the field oxide layers 210a and the doped region 218a with the first conductive type is located beneath each of the shallow trench isolation structures 216a in the well region 202a. The well region 220a with the second conductive type is located in the well region 202a under the isolation region 217a and the source/drain regions 224.

In the invention, the depletion regions respectively exist between the doped region 218a and the well region 220a and between the doped region 220b and the well region 218b. Furthermore each depth of the well regions 220a and 218b is larger than that of the conventional N⁻-type doped regions 116 and 118, so that the intensity of the electric field caused by the high voltage applied on the source/drain region 224 is decreased. Therefore, the crowding electric force lines effect does not occur. Hence. it can provide a bulk breakdown near the source/drain regions 224.

Moreover, the distance between the source/drain region 224 is increased by using the method according to the invention so that the channel length can be greatly increased. Therefore, the short channel effect can be avoided and the method can be applied on the integration of the sub-quarter micron level technique.

It will be apparent to those skilled in the art that various modifications and variations can be made to the structure of the present invention without departing from the scope or spirit of the invention. In view of the foregoing it is intended that the present invention cover modifications and variations of this invention provided they fall within the scope of the following claims and their equivalents.

What is claimed is:

1. A high-voltage device constructed on a substrate, the high-voltage device comprising:
a first well region with a first conductive type located in the substrate:
a plurality of isolation regions on the first well region, wherein each isolation region comprises two field oxide layers on either side of a shallow trench isolation structure:
a gate structure on the first well region between the isolation regions. wherein the gate structure expands onto a portion of the isolation regions;
a source/drain region, with a second conductive type, located in the first well region and exposed by the gate structure and the isolation regions;
a second well region. with the second conductive type, located in the first well region beneath the isolation region and the source/drain region;
a first doped region, with the second conductive type, located in the second well region and beneath each field oxide layer; and
a second doped region. with the first conductive type, located in the second well region and beneath each shallow trench isolation structure.

2. The high-voltage device of claim 1, wherein when the first conductive type is N-type. the second conductive type is P-type.

3. The high-voltage device of claim 1 wherein when the first conductive type is P-type, the second conductive type is N-type.

4. The high-voltage device of claim 1. wherein a dosage of the second doped region is about 1×10¹³ atoms/cm².

5. A method for manufacturing a high-voltage CMOS device on a substrate having a first P-type well region and a first N-type region formed therein, the method comprising the steps of:
forming a plurality of first isolation regions and second isolation regions respectively on the first P-type well and the first N-type well, wherein every first isolation region comprises two first field oxide layers on either side of a first shallow trench isolation structure and every second isolation region comprises two second field oxide layers on either side of a second shallow trench isolation structure, wherein a first N-type doped region and a first P-type doped region are respectively formed beneath each first oxide layer and each second field oxide layer:
forming a second P-type doped region and a second P-type well region respectively beneath each first shallow trench isolation structure and in the first N-type well region under each second isolation region;
forming a second N-type doped region and a second N-type well region respectively beneath the second shallow trench isolation structures and in the first P-type well region under the first isolation regions:
forming a first and a second gate structure respectively on the first P-type well region between the first isolation regions and on the first N-type well region between the second isolation regions;
forming an N-type source/drain region in the second N-type well region exposed by the first gate structure and the first isolation regions: and
forming a P-type source/drain region in the second P-type well region exposed by the second gate structure and the second isolation regions.

6. The method of claim 5, wherein a dosage of the second P-type doped region is about 1×10¹³ atoms/cm².

7. The method of claim 5 wherein a dosage of the second N-type doped region is about 1×10¹³ atoms/cm².

8. The method of claim 5, wherein the step of forming the first and the second isolation regions comprises the steps of:
forming a pad oxide layer and a patterned silicon nitride layer on the substrate in sequence;
forming the first N-type doped region and the first P-type doped region respectively in the first P-type well region and in the first N-type well under the pad oxide layer exposed by the patterned silicon nitride layer;
forming the first field oxide layers and the second field oxide layers respectively on the first N-type doped region and the first P-type doped region; and
forming the first shallow trench isolation structures in every other space between the first field oxide layers in the first P-type well region while the second shallow trench isolation structures are formed in every other space between the second field oxide layers in the first N-type well region. 13
